(19) United States
(12) Patent Application Publication
(10) Pub. No.: US 2021/0041491 A1
(43) Pub. Date: Feb. 11, 2021

(54) DEVICE FOR THIN FILM TRANSISTOR TEST, TEST METHOD, AND ARRAY PANEL

(71) Applicants: BEIJING BOE OPTOELECTRONICS TECHNOLOGY CO., LTD., BEIJING (CN); BOE TECHNOLOGY GROUP CO., LTD., BEIJING (CN)

(72) Inventors: Bin MA, Beijing (CN); Ziwei CUI, Beijing (CN); Yanyan YIN, Beijing (CN); Pengcheng TIAN, Beijing (CN); Xin LI, Beijing (CN)

(21) Appl. No.: 16/099,345

(22) PCT Filed: Mar. 27, 2018
(86) PCT No.: PCT/CN2018/080708

§ 371 Date: Nov. 6, 2018

(30) Foreign Application Priority Data
May 26, 2017 (CN) 201710385385.1

(51) Int. Cl. G01R 31/26; H01L 29/786

(52) U.S. Cl. CPC G01R 31/2601; H01L 29/78633; H01L 29/78618

(57) ABSTRACT

The present disclosure relates to devices for thin film transistor test, test methods, and array panels. A device for thin film transistor test is provided that comprises: a substrate; a thin film transistor provided on the substrate, the thin film transistor including an active layer, a source, a drain, a gate, and a gate insulating layer; a light shielding layer disposed on a side of the active layer, which is away from the substrate, to shield at least an exposed portion of the active layer; a first electrode layer connected to one of the drain and the source; and a second electrode disposed over a surface of the first electrode layer with an intermediate insulating layer interposed therebetween, the surface being away from the substrate, the second electrode layer being connected to at least one of the drain and the source.

### CROSS-REFERENCE TO RELATED APPLICATIONS

The present application claims priority to the Chinese Application No. 201710385385.1 filed on May 26, 2017, which is incorporated in its entirety herein by reference.

### TECHNICAL FIELD

The present disclosure relates to the field of display, and in particular to devices for thin film transistor test, test methods, and array panels.

### BACKGROUND

As the display technology and semiconductor technology develop, people's requirements on the image quality of display screen is getting higher. It is desirable that a display screen such as a liquid crystal panel has a sufficiently high pixel density and a wide color gamut to satisfy the requirements for image quality and picture saturation. For example, for liquid crystal display devices, higher and higher pixel density (Pixels Per Inch, PPI) makes defects be easily generated in the liquid crystal screen. On the other hand, in a high pixel density display device, many defects are related to the switching characteristics of thin film transistors (TFTs) on the array panel (which may also be termed as array substrate). Therefore, if the electrical characteristics of the TFT switches (especially the TFTs in the display area) can be accurately monitored, these defects can be accurately monitored. Thus, it may be advantageous to provide an improved solution.

### SUMMARY

According to an aspect of the present disclosure, a device for thin film transistor test is provided that comprises: a substrate; a thin film transistor provided on the substrate, the thin film transistor including an active layer, a source, a drain, a gate, and a gate insulating layer; a light shielding layer disposed on a side of the active layer, which is away from the substrate, to shield at least an exposed portion of the active layer; a first electrode layer connected to one of the drain and the source; and a second electrode disposed over a surface of the first electrode layer with an intermediate insulating layer interposed therebetween, the surface being away from the substrate, the second electrode layer being connected to at least one of the drain and the source.

In an embodiment, the device for thin film transistor test further comprises: a first resistor having two ends respectively connected to one of the drain and the source and to the second electrode layer.

In an embodiment, the device for thin film transistor test further comprises: a second resistor having two ends respectively connected to the other of the drain and the source and to the second electrode layer.

In an embodiment, the substrate is a substrate for an array panel.

In an embodiment, the thin film transistor further comprises: an insulating layer covering at least the source, the drain, and a surface of the first electrode layer away from the substrate, the light shielding layer being disposed on a surface of the insulating layer away from the substrate.

In an embodiment, the thin film transistor further comprises: an insulating layer covering at least the source, the drain, and a surface of the first electrode layer away from the substrate, wherein the light shielding layer is at least a part of the insulating layer, which part is incorporated with a light-shielding material.

In an embodiment, the light shielding layer is formed of a black resin.

In an embodiment, the device for thin film transistor test is used with an array panel, wherein the substrate serves as a substrate for the array panel.

In an embodiment, the first electrode layer and the second electrode layer are each formed of a light-transmitting and conductive material.

In an embodiment, the source and drain are separated from each other and respectively in contact with the active layer such that a portion of the active layer is exposed.

In an embodiment, the device for thin film transistor test further comprises: a plurality of terminals which are respectively connected to the source, the drain and the first electrode layer for electrical connections to outside.

According to another aspect of the present disclosure, an array panel is provided that comprises: the device for thin film transistor test according to any one of the embodiments.

In an embodiment, the array panel further comprises: an array of other thin film transistors formed on the substrate; and a common electrode.

According to another aspect of the present disclosure, a method of testing thin film transistor is provided that comprises: providing a device for thin film transistor testing, the device for thin film transistor testing comprising: a substrate; a thin film transistor provided on the substrate, the thin film transistor including an active layer, a source, a drain, a gate, and a gate insulating layer; a light shielding layer disposed on a side of the active layer, which is away from the substrate, to shield at least an exposed portion of the active layer; a first electrode layer connected to one of the drain and the source; and a second electrode disposed over a surface of the first electrode layer with an intermediate insulating layer interposed therebetween, the surface being away from the substrate, the second electrode layer being connected to at least one of the drain and the source, and applying voltage(s) to one or more of the source, the drain, and the gate of the thin film transistor, and detecting corresponding electrical parameter(s).

In an embodiment, the substrate comprises a substrate for an array panel; wherein providing a device for thin film transistor testing comprises: disposing the device for thin film transistor testing in a non-display area of the array panel; and wherein the thin film transistor in the device for thin film transistor test is configured to simulate thin film transistor(s) in a display area of the array panel.

In an embodiment, the device for thin film transistor test further comprises: a first resistor having two ends respectively connected to one of the drain and the source and to the second electrode layer, the first resistor being configured such that a divided voltage on the second electrode layer is capable of simulating a voltage of a common electrode of the array panel.

In an embodiment, the device for thin film transistor test further comprises: a second resistor having two ends respectively connected to the second electrode layer and the other of the drain and the source, the second resistor being configured such that the divided voltage on the second electrode layer is capable of simulating the voltage of the common electrode of the array panel.

In an embodiment, the thin film transistor further comprises: an insulating layer covering at least the source, the drain, and a surface of the first electrode layer which is away from the substrate, the light shielding layer being disposed on a surface of the insulating layer which is away from the substrate.

In an embodiment, the thin film transistor further comprises: an insulating layer covering at least the source, the drain, and a surface of the first electrode layer which is away from the substrate, wherein the light shielding layer is at least a part of the insulating layer, which part is incorporated with a light shielding material.

In an embodiment, the first electrode layer and the second electrode layer are each formed of a light-transmitting and conductive material.

In an embodiment, the source and drain are separated from each other, and respectively in contact with the active layer, such that a portion of the active layer is exposed.

According to various aspects and embodiments of the present disclosure, the accuracy of detection can be improved, and substrate yield and performance can be improved.

### BRIEF DESCRIPTION OF DRAWINGS

The above and/or additional aspects and advantages of the present disclosure will become apparent and readily understood from the description of the embodiments in conjunction with drawings in which:

FIG. 1A is a schematic cross-sectional view showing a structure of a device for thin film transistor test according to an embodiment of the present disclosure;

FIG. 1B is a schematic cross-sectional view showing a structure of a device for thin film transistor test according to another embodiment of the present disclosure;

FIG. 2 is a schematic plan view of a portion of a conventional device for thin film transistor test;

FIG. 3 shows a schematic top view of a portion of a device for thin film transistor test in accordance with an embodiment of the present disclosure;

FIG. 4 shows a flow chart of a test method according to an embodiment of the present disclosure;

FIG. 5 is a flow chart showing a test method according to another embodiment of the present disclosure;

FIG. 6 is a flow chart showing a test method according to a further embodiment of the present disclosure;

FIG. 7 is a view showing a test result of the prior art device for thin film transistor test before assembling of the panels;

FIG. 8 is a view showing a test result of the conventional device for thin film transistor test after assembling of panels.

Note that, in the embodiments described below, the same reference numerals are sometimes used to refer to the same parts or the parts having the same functions, and the repeated description is thus omitted. In the present specification, like reference numerals and letters are used to indicate like items, and therefore, once an item is defined in one drawing, it is not necessary to further discuss it in the description of the subsequent drawings.

### DESCRIPTION OF THE REFERENCE SIGNS

100: substrate; 200: thin film transistor; 210: gate; 220: active layer; 230: source; 240: drain; 250: light shielding layer; 300: first electrode layer; 400: second electrode layer; 10: insulating layer; 20: connection line; 500: second resistor; 600: first resistor.

### DETAILED DESCRIPTION OF ILLUSTRATIVE EMBODIMENTS

Some example embodiments of the present disclosure are described in detail below with reference to the drawings. In the figures, the same or similar elements are used to denote the same or similar elements, steps or items, or the elements, steps or items having the same or similar functions. The embodiments described below are illustrative only and are not to be construed as limiting the scope of the invention as defined by the appended claims.

In order to facilitate the detection of the electrical characteristics of the thin film transistor of the display area, a thin film transistor test group (also commonly referred to as a test teg) device is usually disposed in a non-display area of an array panel of a thin film transistor liquid crystal display (TFT-LCD). The thin film transistor in the device of thin film transistor test group is used to simulate the thin film transistor of the display area, thereby realizing the detection of the switching characteristics of the TFTs the display area. However, the inventors have found that in the current test group device, it is ubiquitous that the test result is difficult to accurately reflect the switching characteristics of the TFT in the actual display area.

After massive and in-depth research and a large number of experiments, the inventors of the present application have found that one possible reason is: the working environment of the thin film transistor disposed in the test group device in the non-display area is different from the working environment of the thin film transistor disposed in the display area. Therefore, in the prior art, when testing is performed with the test group device, the influence of the actual environment on the switching characteristics of the thin film transistor in the display area is not considered, thereby causing the switching characteristics of the thin film transistor obtained by the test group device do not match the actual switching characteristics of the TFTs in the display area.

In one aspect of the disclosure, a device for thin film transistor test is proposed. The device for thin film transistor test can be adaptable to be disposed in a non-display area of an array panel. The switching characteristics of the thin film transistor in the display area of the array panel can be evaluated by perform test on the device for thin film transistor test, for example, before the array panel and a panel (e.g., pixel panel, etc.) which mated with the array panel is assemblied.

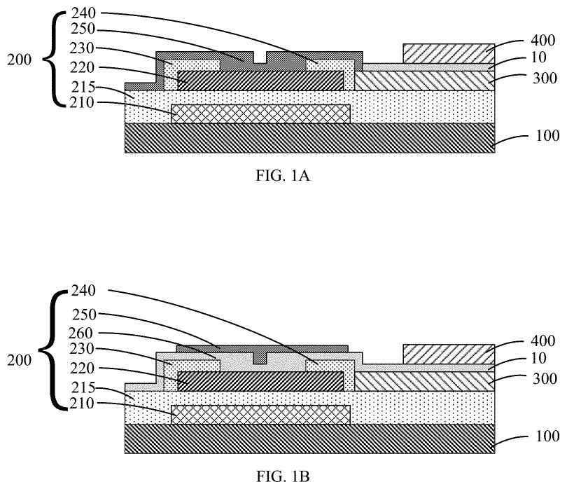

FIG. 1A shows a schematic cross-sectional view of a structure of a device for thin film transistor test according to an embodiment of the present disclosure. Referring to FIG. 1A, the device for thin film transistor test may include: a substrate 100, and a thin film transistor 200 provided on the substrate 100. The thin film transistor 200 may include an active layer 220, a source 230 and a drain 240, a gate 210, and a gate insulating layer 215. In the embodiment shown in FIG. 1A, the gate 210 is disposed over a substrate 100, and the gate insulating layer 215 is shown as being formed over the substrate on which the gate 210 is formed, and covering the gate 210. The active layer 220 is formed on the gate insulating layer 215. The active layer 220 may be formed of a semiconductor material. The source 230 and the drain 240 are formed in contact with the active layer 220. Although in FIG. 1A, the source 230 and the drain 240 are each shown as a portion thereof being formed on the active layer 220 and another portion covering the side of the active layer 220, it is apparent that the present disclosure is not limited thereto. The source 230 and the drain 240 are separated from each other such that a portion of the active layer 220 is exposed. The source 230 and the drain 240 may each be formed of a conductive material such as, but not limited to, metal, polysilicon or the like.

It should be noted that the thin film transistor 200 may have a substantially same structure as the thin film transistor disposed in the display area of the array panel. In some embodiments, the thin film transistor disposed in the display area of the array panel may have a gate, a gate insulating layer, an active layer, a source, and a drain as what are substantially the same as those of the thin film transistor 200 disposed in the non-display area. For example, the gate, the gate insulating layer, the active layer, the source, and the drain of the thin film transistor disposed in the display area of the array panel may be formed to have substantially the same sizes as the gate, the gate insulating layer, the active layer, the source and the drain in the thin film transistor 200 disposed in the non-display area, respectively, and may be formed from substantially the same material using substantially the same process as the gate, the gate insulating layer, the active layer, the source and the drain in the thin film transistor 200 disposed in the non-display area, respectively.

It should also be understood that only the components that may be involved in describing the example embodiments of the present disclosure are shown in the figures, and features that may not be referred to or not addressed by these embodiments are not shown.

The device for thin film transistor test may further include a light shielding layer 250. The light shielding layer 250 may be disposed on a side of the active layer 220, which is away from the substrate 100, as shown in FIG. 1A. The light shielding layer 250 may be disposed corresponding to the active layer 220. The light shielding layer can be used to shield at least the exposed portion of the active layer. For example, the light shielding layer may be used to shield at least a portion of the active layer 220 which is exposed through the source and source. The light shielding layer 250 may be formed from a black resin. The light shielding layer 250 may also be at least a portion of a certain insulating layer, said at least a portion of the insulating layer being added with light shielding material(s). With the light shielding layer 250, the influence of irradiation (for example, by ultraviolet (UV) rays) in a subsequent process step on the active area of the thin film transistor 220 can be reduced, so that the electrical properties of the thin film transistor 200 are closer to or consistent with that of the TFT(s) in the display area.

The device for thin film transistor test may further include a first electrode layer 300 and a second electrode layer 400. The first electrode layer 300 may be connected to one of the source and the drain (e.g., the drain 240). The second electrode layer 400 may be disposed on a surface of the first electrode layer 300, which is remote from the substrate 100, with an insulating layer 10 interposed therebetween. The second electrode layer 400 may be connected to at least one of the drain 240 and the source 230. Each of the first electrode layer 300 and the second electrode layer 400 may be formed of a light-transmitting and conductive material such as, but not limited to, ITO, IZO, or the like. The first electrode layer 300 may be used to simulate the ITO electrode or wiring in a pixel which is connected to the TFT in the display area. And, the second electrode 400 may be used to simulate the influence of, for example, a common electrode of the array panel on the pixel ITO electrode or wiring (e.g., due to parasitic capacitance, capacitive coupling, etc.).

Thereby, the light shielding layer and/or the first and second electrode layers can be utilized to simulate the electrical environment when the TFT(s) in the display area is operated, therefore the accuracy of the data obtained from the test which is conducted with the device for thin film transistor test is improved.

Here, it should be understood that the structure shown in FIG. 1A is merely exemplary; the present disclosure is not limited to the configuration shown in FIG. 1A. For example, in FIG. 1A, the gate insulating layer 215 may be shown as that the thickness of the portion thereof on both sides of the gate 210 is thicker than the thickness of the portion on the gate 210 such that its upper surface is substantially flat. In other embodiments, however, the gate insulating layer 215 may be formed such that the thickness of the portions thereof on both sides of the gate 210 is substantially consistent with the thickness of the portion thereof on the gate 210. Although in FIG. 1A, the source 230 and the drain 240 are shown as their outer sidewalls are substantially vertical, the disclosure is not limited thereto. For example, in other embodiments, the source 230 and the drain 240 each may also include an extension (not shown) extending further outward from the respective outer sidewalls on the gate insulating layer 215. In some embodiments, the source 230 and the drain 240 can also be configured to not cover the ends of the active layer 220. In this case, preferably, the light shielding layer shields all exposed portions of the active layer, that is, the exposed ends of the active layer 220 are also covered.

The operations and principles of the device for thin film transistor test will be briefly described below.

When testing with the device for thin film transistor test, for example, a fixed voltage can be applied to the source and the drain, the gate voltage can be scanned within a certain range, and meanwhile the drain current can be detected, thereby the switching characteristics of the thin film transistor can be determined. Those skilled in the art will readily appreciate that a wide variety of parameters of the thin film transistor can be detected by different test methods or steps. However, since the device for thin film transistor test is usually disposed in the non-display area, the accuracy of the test result by the device for thin film transistor test depends on whether the thin film transistor 200 in the device for thin film transistor test can truly reflect the thin film transistor in the display area. That is to say, in order to enable the device for thin film transistor test to obtain test results more accurately, in addition to that the thin film transistor 200 is set to have the same structure and composition as the TFT in the display area, it may be advantageous to also set the electrical environment in which it is placed to be as close as possible to the electrical environment in which the TFTs in the display area are located.

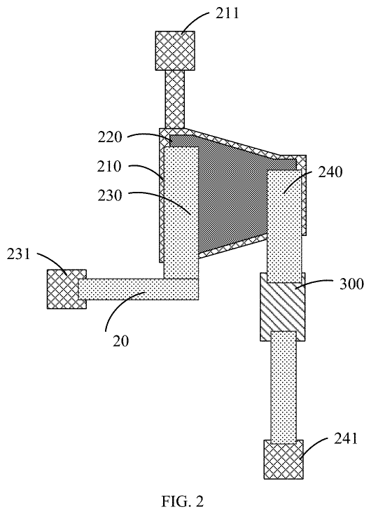

FIG. 2 shows a schematic top view of a portion of a thin film transistor test device of prior art. It will be understood that for clarity and conciseness of the description, in the top view of FIG. 2, some certain layer(s) may be omitted, and some layer(s) which is shielded or partially shielded are not explicitly shown, but only parts of the layers that are involved in the related description are shown. Referring to FIG. 2, the thin film transistor test device of the prior art may have a source 230, a drain 240, a gate 210, and an active layer 220 which form a thin film transistor, and a first electrode layer 300 connected to the drain 240.

Referring to FIG. 2, the active layer 220 is formed over the gate 210 with a gate insulating layer (not shown) interposed therebetween. The drain (which may also be referred to as a drain electrode) 230 and the source (which may also be referred to as a source electrode) 240 are formed over the active layer 220. The first electrode layer 300, the source electrode 230, and the drain electrode 240, etc. are connected to the respective terminals (for example, pads) for connections to the outside, through connection lines 20 formed of conductive material(s) such as metal. For example, a gate pad 211 connected to the gate, a drain pad 231 connected to the drain, and a source pad 241 connected to the source (through the first electrode layer 300) are shown in FIG. 2. The first electrode layer 300 may be formed of a light-transmitting and conductive material. In the testing, different voltages are applied to the three electrodes of the TFT switch (i.e., source 230, drain 240, gate 210) through the pads to monitor the electrical characteristics of the TFT switch.

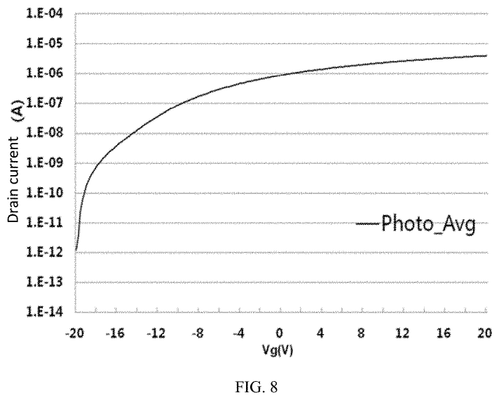

However, the test device having such a structure has a significant difference in the test results before and after the assembling. FIG. 7 shows the relationship between the drain current in a state that the pixels are lit (the drain current being indicated with Photo Avg) and the drain current in a state that the pixels are not lit vs. the gate voltage (Vg) when the thin film transistor test device is disposed on the array panel and the array panel is not assemblied with the color filter substrate. FIG. 8 shows the relationship between the drain current in the state where the pixels are lit (Photo Avg) vs the gate voltage (Vg) after the array panel and the color filter substrate are assemblied (MDL Out). As can be seen, there is a significant change between the switching characteristics of the thin film transistor detected by the test device before and after the assembling.

A purpose of testing through the thin film transistor test device before the assembling is to find out whether the switching characteristics of the thin film transistor on the array panel meet the predetermined standard as early as possible before the assembling, so as to reduce the probability of product failure and save the cost of liquid crystal molecules and the color film substrate assembled with it. If the device for thin film transistor test itself has a large difference in the switching characteristics detected before and after the assembling, the accuracy of the detection result is lowered.

The inventors have conducted in-depth research and a large number of experiments and found that one main cause for the above problems is that, in design for the structure as shown in FIG. 2, only the electrical characteristics of the channels of the switches are considered, and the entire electrical environment, which the thin film transistors are located in when the pixels in the pixel area are lit, is not considered. For the thin film transistors of the display area of the array panel, the environment after the assembling is the environment in which the thin film transistor is actually operated in practice. On the other hand, since the thin film transistor test device has only one first electrode layer, the influence of the electric field generated by the pixel electrode on the thin film transistor can only be simulated by the electrode layer. In fact, when the thin film transistor in the display area operates, the electric field generated between the common electrode and the pixel electrode also has an influence on the TFT switching characteristics. In addition, when the liquid crystal assembly is lit after the assembling, the illumination of the light also has a non-negligible influence on the TFT switching characteristics at the channel. The thin film transistor test device of the prior art as shown in FIG. 2 fails to recognize, no mention take into account, the influence of the above factors.

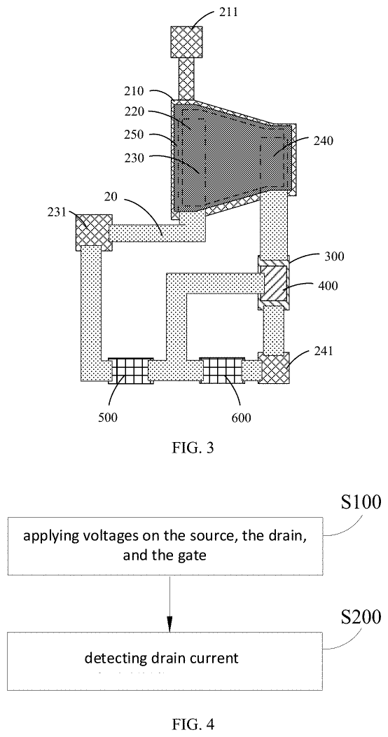

FIG. 3 shows a schematic top view of a portion of a device for thin film transistor test in accordance with an embodiment of the present disclosure. An improvement to the scheme shown in FIG. 2 is schematically illustrated in FIG. 3. In FIG. 3, the same reference numerals are used to denote the components as same as or corresponding to the respective ones shown in FIG. 2, and the repeated description thereof will be omitted here. The device for thin film transistor test according to an embodiment of the present disclosure may include a source 230, a drain 240, a gate 210, and an active layer 220 which form a thin film transistor, and a first electrode layer 300 connected to the drain 240. The first electrode layer 300, the source electrode 230, the drain electrode 240, and the like are connected to respective terminals (for example, pads) for connections to the outside, through connection members 20 formed of conductive material(s) such as metal. A gate pad 211 connected to the gate, a drain pad 231 connected to the drain, and a source pad 241 connected to the source (through the first electrode layer 300) are shown in FIG. 3.

In contrast to the thin film transistor test device shown in FIG. 2, a second electrode layer 400 is further provided in accordance with some embodiments of the present disclosure. The second electrode layer 400 is disposed on a side of the first electrode layer 300 which is away from the substrate, and insulative from the first electrode layer 300. Thus, the device for thin film transistor test according to the embodiments of the present disclosure has two electrode layers, so that the common electrode and the pixel electrode can be simulated, and the influence of the common electrode and the pixel electrode on the switching characteristics of the thin film transistor 200 can be simulated in testing. Here, an insulating layer 10 therebetween is not shown in FIG. 3.

According to some embodiments of the present disclosure, the device for thin film transistor test is generally disposed in a non-display area of an array panel. That is, the substrate 100 may be a substrate of the array panel. For purpose of narrow frame and the like, the non-display area of the array panel generally is not provided with much lead terminals. In view of this, in some embodiments of the present disclosure, the second electrode layer 400 may be connected to at least one of the source 230 and the drain 240, thereby the second electrode layer 400 been applied with a certain voltage by means of the voltages applied at the source 230 and the drain 240 during test, and thus such an effect can be achieved that the common electrode can be simulated.

According to an embodiment of the present disclosure, referring to FIG. 3, the device for thin film transistor test may further include a first resistor 600. The first resistor 600 is disposed between the second electrode layer 400 and one of the source and the drain (here, the drain 240). Both ends of the first resistor 600 are connected to one of a source and a drain (here, the drain 240) and the second electrode layer 400, respectively. Thereby, the voltage applied to the drain can be supplied to the second electrode layer 400 by means of the first resistor (here, an appropriate voltage drop can be formed on the resistor 500), so that an appropriate voltage can be supplied to the second electrode layer 400 so as to simulate, with use of the second electrode layer 400, the influence of the common electrode on the thin film transistor in the display area. According to some embodiments of the present disclosure, the device for thin film transistor test may further include a second resistor 500. The second resistor 500 may be disposed between the second electrode layer 400 and the other of the source and the drain (here, the source 230). Both ends of the second resistor 500 are connected to the source 230 and the second electrode layer 400, respectively. Thereby, the voltage applied to the source 230 can be divided (for example, a voltage drop is formed on the resistor 500) by the second resistor 500 and supplied to the second electrode layer 400.

According to some embodiments of the present disclosure, a second resistor 500 may be disposed between the source 230 and the second electrode layer 400, and a first resistor 600 may be disposed between the drain 240 and the second electrode layer 400, as shown in FIG. 3. Thereby, voltage dividing can be performed by the first resistor and the second resistor to provide an appropriate voltage to the second electrode layer 400. In a specific example of a test using the device for thin film transistor test, voltages having fixed values may be applied to the source 230 and the drain 240, respectively, and the voltage applied to the gate 210 may be scanned within a certain range, and the current values of the drain current under different gate voltages are detected.

It should be noted that in the context of the present disclosure, the term “connect” or other variations thereof may refer to, but is not limited to, at least one of the following: a physical connection and/or an electrical connection. Additionally, the term “connect” can include both directly connecting and indirectly connecting. Accordingly, it should be understood that although in FIG. 3 the resistors are shown as being connected to respective terminals, they can be connected to the corresponding electrodes through the respective terminals and corresponding connection lines or other components (e.g., the first electrode layer, as needed). In general, the connection lines or other components are basically formed of material(s) which is used for an electrode, thus their electric resistances are relatively low, and in some cases can even be neglected.

In addition, it should also be understood that, for clarity of illustration, possible connecting components (e.g., vias, etc.) between different conductive layers are not shown in FIGS. 2 and 3.

There is no particular limitation on the specific values of the voltages applied to the source, the drain, and the gate, and those skilled in the art can set them according to actual conditions. For example, when testing multiple batches of products, the same settings can be used for the tests to facilitate comparisons of product performances. The specific values of the first resistor 600 and the second resistor 500 can be determined according to the voltages of the source and the drain, and the value of the voltage actually required to be applied to the common electrode layer on the array panel corresponding to the product.

In the embodiment shown in FIG. 3, since the voltages applied to the source 230 and the drain 240 are different, and the voltage difference between the source and the drain is divided by the second resistor and the first resistor, thus a desired partial pressure can be supplied to the second electrode layer 400. Thereby, the simulation of the influence of the common electrode, and the common electrode on the TFT, can be achieved without providing additional pads or terminals.

According to some embodiments of the present disclosure, as shown in FIG. 3, the thin film transistor may further include a light shielding layer such as the light shielding layer 250. Thereby, it is possible to simulate the environment in which the active layer 240 is located in a state where the display area is lit after the assembling. Here, as shown in FIGS. 1A and 3, the light shielding layer 250 covers the exposed portion of the active layer 220 (that is, the portion not covered by the source 230 and the drain 240), and also covers the source 230 and the drain 240. Therefore, in FIG. 3, the outline of the active area covered by the source 230, the drain 240, and the light shielding layer 250 is shown by dash-line, and the outline of the portions of the source 230 and the drain 240 covered by the light shielding layer 250 shown by dash-dot-line.

In addition, although the first electrode 300 is illustrated as being in direct contact with the drain (or drain line) 240 in FIGS. 1A and 1B, the present disclosure is not limited thereto; for example, in the exemplary embodiment shown in FIG. 3, the first electrode 300 can also be connected to the drain 240 through an additional lead.

Since the thin film transistor test device shown in FIG. 2 is not provided with the light shielding layer, the environment that the active layer in the thin film transistor is located is different from the environment after the panel is assemblied and lit (i.e., the environment under working conditions of the display device). Since the active layer may generally made of a light-sensitive polysilicon material (for example, a high-resistance polysilicon material), this factor also has a substantial influence on the switching characteristics of the thin film transistor. Therefore, the measurement results of the thin film transistor test device of prior art may deviate from the actual parameters of the TFT devices in the display area. According to the device for thin film transistor test of the embodiments of the present disclosure, the above problem can be largely alleviated, thereby making the test result more accurate and reliable.

According to some embodiments of the present disclosure, the specific arrangements, materials, and structures of the light shielding layer 250 are not particularly limited, and can be selected by those skilled in the art according to actual conditions. For example, according to an embodiment of the present disclosure, an insulating layer may be provided in the thin film transistor 200, and the insulating layer may be disposed on a surface of the source, the drain, and the first electrode layer, which is away from the substrate. At least a portion of the insulating layer is then added with a light-shielding material, such as a black dye, to form the light-shielding layer 250 to shield light. For example, said at least a portion may correspond to an exposed portion of the active layer. Alternatively, according to further embodiments of the present disclosure, the light shielding layer 250 may also be separately provided or additionally added.

The light shielding layer 250 may be separately formed, for example, using a black resin.

FIG. 1B shows a schematic cross-sectional view of a structure of a device for thin film transistor test according to another embodiment of the present disclosure. As shown in FIG. 1B, a light shielding layer 250 may be additionally formed over the insulating layer 260 disposed on the surface of the source, the drain, and the first electrode layer, the surface being away from the substrate. The same reference numerals are used to indicate the components in the embodiment shown in FIG. 1B which are the same as the respective ones shown in FIG. 1A, and the repeated descriptions on these same components will be omitted here. In addition, in the embodiment shown in FIG. 1B, the insulating layer 260 and the insulating layer 10 may be formed of a same layer of insulating material.

In other embodiments, the light shielding layer may be formed of a material which can be used to form a black matrix. In some embodiments, the light shielding layer can be utilized to act as a black matrix structure. According to the embodiment of the present disclosure, the working environment of the thin film transistor in the state that the display area is lit can be more accurately and reliably simulated, so that a more accurate and reliable detection structure can be obtained.

In another aspect of the present disclosure, an array panel is provided that can include a device for thin film transistor test according to any of the embodiments of the present disclosure and any other embodiments that can be readily derived from the present disclosure. The array panel may further include an array formed of other thin film transistors formed on the substrate thereof; and a common electrode. Thus, the array panel has all of the features and advantages of the previously described device for thin film transistor test. In particular, according to the array panel of the present disclosure, the test result of the device for thin film transistor test is closer to the actual situation of the thin film transistor in the display area, thereby it is advantageous for discovering potential defects (if any) in the substrate more accurately. Thus, the costs in mass production can be reduced, for example, the preparation of display panels having defects therein can be avoided, and unnecessary waste can be avoided, etc.). In addition, since the potential defects in the substrate can be more accurately found, it is possible to further improve the array panel. And, the improvement is well-directed. Thereby production efficiency and the yield can be directly or indirectly improved, and the manufacturing cost of the display panel can be reduced. In yet another aspect of the present disclosure, a test method for a device for thin film transistor test is proposed. According to some embodiments of the present disclosure, the test method may be suitably or adaptively used with the device for thin film transistor test according to any of the embodiments of the present disclosure and any other embodiment that can be apparently obtained according to the present disclosure. FIG. 4 shows a flow diagram of a test method in accordance with one embodiment of the present disclosure.

Referring to FIG. 4, the method includes:

S100: applying voltages on the source, the drain, and the gate.

According to some embodiments of the present disclosure, in this step, voltages are applied to the source, the drain, and the gate, respectively. As an example, the voltages applied to the source and the drain may be fixed voltages. For example, a voltage of 0 V may be applied to the source and a voltage of 15 V may be applied to the drain; and the gate voltage may be scanned within a range of −20 to 20 V.

S200: detecting drain current.

In this step, the drain current is detected while scanning the gate voltage. The test method according to an embodiment of the present disclosure can better simulate the environment in which the thin film transistor of the display area is actually operated, so that the accuracy of the test result can be improved.

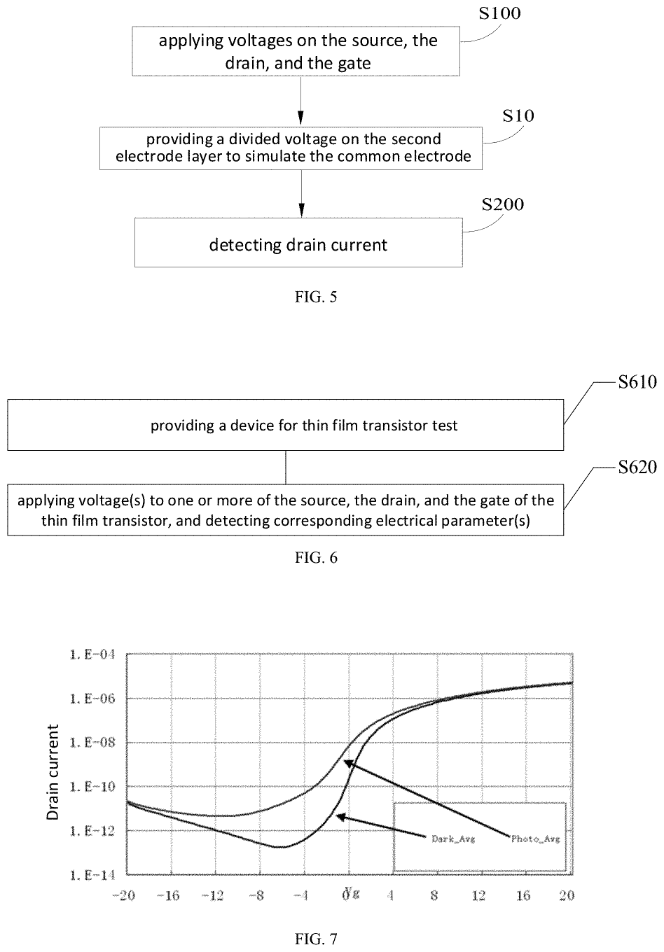

FIG. 5 shows a flow chart of a test method according to another embodiment of the present disclosure. Referring to FIG. 5, according to further embodiments of the present disclosure, the test method may further include:

S10: providing a divided voltage on the second electrode layer to simulate the common electrode.

A device for thin film transistor test suitable for the method may include a first resistor and/or a second resistor. Regarding the disposing positions and the principles of the first resistor and the second resistor, detailed descriptions have been made above, and thus are not repeated herein. According to some embodiments of the present disclosure, in this step, the first resistor and/or the second resistor may be utilized such that the second electrode layer has a certain divided voltage. In some embodiments, the resistance(s) of the first resistor and/or the second resistor may be designed in conjunction with the voltages applied to the source and the drain, so as to provide a suitable voltage to the second electrode layer. Thereby, it is possible to simulate the influence of the common electrode of the array panel on the TFT in the display area in the operating state. Thus, the accuracy of the test performed by the method can be further improved.

FIG. 6 shows a flow chart of a test method according to still another embodiment of the present disclosure. As shown in FIG. 6, the thin film transistor test method may comprise: in step S610, providing a device for thin film transistor test. The device for thin film transistor test can be a device for thin film transistor test according to any of the embodiments of the present disclosure and any other embodiment that can be apparently obtained in accordance with the present disclosure. For example, in some implementations, the device for thin film transistor test may comprise: a substrate; a thin film transistor on the substrate, the thin film transistor including an active layer, a source, a drain, a gate, and a gate insulating layer; a light shielding layer disposed on a side of the active layer, which is away from the substrate, to shield at least an exposed portion of the active layer; a first electrode layer connected to one of the drain and the source; and a second electrode layer disposed on a surface of the first electrode layer with an intermediate insulating layer interposed therebetween, the surface of the first electrode layer being away from the substrate, the second electrode layer being coupled to at least one of the drain and the source. The method may further comprise: in step S620, applying voltage(s) to one or more of the source, the drain, and the gate of the thin film transistor, and detecting corresponding electrical parameter(s). In some implementations, the electrical parameter(s) can comprise any suitable parameter for a transistor, such as but not limited to, current/voltage/capacitance of one or more electrodes of the thin film transistor, various characteristic curves of the transistor, etc.

In some embodiments, the substrate comprises a substrate for an array panel. In some embodiments, the device for thin film transistor test may further comprise: a first resistor, two ends of the first resistor being respectively connected to the second electrode layer and one of the drain and source, respectively. The first resistor is configured such that a divided voltage on the second electrode layer can simulate a voltage of a common electrode of the array panel. In some embodiments, the device for thin film transistor test may further comprise: a second resistor, two ends of the second resistor being respectively connected to the second electrode layer and the other of the drain and the source. The second resistor is configured such that a divided voltage on the second electrode layer can simulate a voltage of a common electrode of the array panel.

In some embodiments, the thin film transistor may further comprise: an insulating layer covering at least the source, the drain, and a surface of the first electrode layer, the surface being away from the substrate. The light shielding layer is disposed on a surface of the insulating layer, which is away from the substrate. In some embodiments, the thin film transistor further comprises: an insulating layer covering at least the source, the drain, and a surface of the first electrode layer, the surface being away from the substrate. The light shielding layer can be at least a portion of the insulating layer, and said at least a portion of the insulating layer is added with a light blocking material.

In some embodiments, the first electrode layer and the second electrode layer are each formed of a light-transmissive and conductive material. In some embodiments, the source and drain are separated from each other and are respectively in contact with the active layer so that a portion of the active layer is exposed.

In general, the method has at least one of the following advantages: test accuracy is improved, and method is simple.

In the description of the present disclosure, the orientations or positional relationships indicated with the terms “upper”, “lower”, and the like are based on the orientations or positional relationships shown in the drawings, and is merely for the convenience of describing the present disclosure and not for limiting the present disclosure to the embodiments thus constructed or operated in such particular orientations, therefore shall not be construed as limiting for the disclosure. Embodiments of the present disclosure can be implemented in a different orientation from those shown in the figures.

In the description of the present specification, the terms “an embodiment”, “another embodiment” or the like are intended to mean that the specific features, structures, materials or characteristics described in connection with the embodiment are included in at least one embodiment of the present disclosure. In the present specification, the schematic representation of the above terms is not necessarily directed to the same embodiment or example. Furthermore, the particular features, structures, materials, or characteristics described may be combined in any one or more embodiments or examples as appropriate. In addition, those skilled in the art will readily appreciated that various embodiments or examples described in the specification, as well as the feature(s) of various embodiments or examples, may be combined unless the context or the principles indicate otherwise.

While some embodiments of the present disclosure have been shown and described above, it is to be understood that the above-described embodiments are illustrative and shall not to be construed as limiting the scope of the disclosure. Variations, modifications, substitutions and variations can be made by those skilled in the art to the above embodiments without departing from the scope and spirit of the present disclosure.

1. A device for thin film transistor test comprising:
a substrate;
a thin film transistor provided on the substrate, the thin film transistor including an active layer, a source, a drain, a gate, and a gate insulating layer;
a light shielding layer disposed on a side of the active layer, which is away from the substrate, to shield at least an exposed portion of the active layer;
a first electrode layer connected to one of the drain and the source; and
a second electrode disposed over a surface of the first electrode layer with an intermediate insulating layer interposed therebetween, the surface being away from the substrate, the second electrode layer being connected to at least one of the drain and the source.

2. The device for thin film transistor test according to claim 1, further comprising:
a first resistor having two ends respectively connected to one of the drain and the source and to the second electrode layer.

3. The device for thin film transistor test according to claim 2, further comprising:
a second resistor having two ends respectively connected to the other of the drain and the source and to the second electrode layer.

4. The device for thin film transistor test according to claim 1, wherein the substrate is a substrate for an array panel.

5. The device for thin film transistor test of claim 1, wherein the thin film transistor further comprises:
an insulating layer covering at least the source, the drain, and a surface of the first electrode layer away from the substrate, the light shielding layer being disposed on a surface of the insulating layer away from the substrate.

6. The device for thin film transistor test of claim 1, wherein the thin film transistor further comprises:
an insulating layer covering at least the source, the drain, and a surface of the first electrode layer away from the substrate,
wherein the light shielding layer is at least a part of the insulating layer, which part is incorporated with a light-shielding material.

7. The device for thin film transistor test according to claim 1, wherein the light shielding layer is formed of a black resin.

8. The device for thin film transistor test according to claim 1, wherein the device for thin film transistor test is used with an array panel, wherein the substrate serves as a substrate for the array panel.

9. The device for thin film transistor test according to claim 1, wherein the first electrode layer and the second electrode layer are each formed of a light-transmitting and conductive material.

10. The device for thin film transistor test according to claim 1, wherein the source and drain are separated from each other and respectively in contact with the active layer such that a portion of the active layer is exposed.

11. (canceled)

12. An array panel comprising:
the device for thin film transistor test according to claim 1.

13. The array panel of claim 12, further comprising:
an array of other thin film transistors formed on the substrate; and
a common electrode.

14. A method of testing thin film transistor, comprising:
providing a device for thin film transistor testing, the device for thin film transistor testing comprising:
a substrate;
a thin film transistor provided on the substrate, the thin film transistor including an active layer, a source, a drain, a gate, and a gate insulating layer;
a light shielding layer disposed on a side of the active layer, which is away from the substrate, to shield at least an exposed portion of the active layer;
a first electrode layer connected to one of the drain and the source; and
a second electrode disposed over a surface of the first electrode layer with an intermediate insulating layer interposed therebetween, the surface being away from the substrate, the second electrode layer being connected to at least one of the drain and the source, and
applying voltage(s) to one or more of the source, the drain, and the gate of the thin film transistor, and detecting corresponding electrical parameter(s).

15. The method of claim 14,
wherein the substrate comprises a substrate for an array panel;
wherein providing the device for thin film transistor testing comprises: disposing the device for thin film transistor testing in a non-display area of the array panel; and
wherein the thin film transistor in the device for thin film transistor test is configured to simulate one or more thin film transistors in a display area of the array panel.

16. The method of claim 15, wherein the device for thin film transistor test further comprises:
a first resistor having two ends respectively connected to one of the drain and the source and to the second electrode layer, the first resistor being configured such that a divided voltage on the second electrode layer is capable of simulating a voltage of a common electrode of the array panel.

17. The method of claim 16, wherein the device for thin film transistor test further comprises:
a second resistor having two ends respectively connected to the second electrode layer and the other of the drain and the source, the second resistor being configured such that the divided voltage on the second electrode layer is capable of simulating the voltage of the common electrode of the array panel.

18. The method of claim 14, wherein the thin film transistor further comprises:
an insulating layer covering at least the source, the drain, and a surface of the first electrode layer which is away from the substrate, the light shielding layer being disposed on a surface of the insulating layer which is away from the substrate.

19. The method of claim 14, wherein the thin film transistor further comprises:
an insulating layer covering at least the source, the drain, and a surface of the first electrode layer which is away from the substrate,
wherein the light shielding layer is at least a part of the insulating layer, which part is incorporated with a light shielding material.

20. The method of claim 14, wherein the first electrode layer and the second electrode layer are each formed of a light-transmitting and conductive material.

21. The method of claim 14, wherein the source and drain are separated from each other, and respectively in contact with the active layer, such that a portion of the active layer is exposed.
